(19) United States
(12) Patent Application Publication
(10) Pub. No.: US 2018/0254170 A1
(43) Pub. Date: Sep. 6, 2018

(54) PLASMA GENERATING APPARATUS AND METHOD OF MANUFACTURING PATTERNED DEVICES USING SPATIALLY RESOLVED PLASMA PROCESSING

(71) Applicants: TOTAL S.A., Courbevoie (FR); ECOLE POLYTECHNIQUE, Palaiseau (FR); CENTRE NATIONAL DE LA RECHERCHE SCIENTIFIQUE, Paris Cedex 16 (FR)

(72) Inventors: Erik JOHNSON, PARIS (FR); Bastien BRUNEAU, PARIS (FR); Pere ROCA I CABARROCAS, VILLEBON SUR YVETTE (FR); Pavel BULKIN, VILLEBON SUR YVETTE (FR); Nada HABKA, BOURG LA REINE (FR)

(21) Appl. No.: 15/756,103

(22) PCT Filed: Aug. 30, 2016
(86) PCT No.: PCT/EP2016/070421

§ 371 Date: Feb. 28, 2018

(30) Foreign Application Priority Data
Aug. 31, 2015 (EP) 15306338.3

(51) Int. Cl. H01J 37/32; C23C 16/04; C23C 16/455; C23C 16/505; H01L 31/0392; H01L 31/20

(52) U.S. Cl. CPC H01J 37/32091; C23C 16/045; C23C 16/45565; C23C 16/505; H01L 31/202; H01J 37/32541; H01J 37/32568; H01J 37/32816; H01L 31/03921; H01J 37/32366

(57) ABSTRACT

Disclosed is a plasma generating apparatus, for manufacturing devices having patterned layers, including a first electrode assembly and a second electrode assembly placed in a plasma reactor chamber, an electrical power supply for generating a voltage difference between the first electrode assembly and the second electrode assembly. The first electrode assembly includes a plurality of protrusions and a plurality of recesses, the protrusions and recesses being dimensioned and set at respective distances from the surface of the substrate so as to generate a plurality of spatially isolated plasma zones located selectively either between the second electrode assembly and the plurality of recesses or between the second electrode assembly and the plurality of protrusions.

### TECHNICAL FIELD OF THE INVENTION

The invention relates to an apparatus and a method for generating and handling plasma used for deposition and/or etching of materials.

More precisely the invention relates to an apparatus and a method for producing devices incorporating patterned thin film produced by plasma deposition and/or plasma etching at a moderate cost compared to conventional masking, photolithography, or laser processing steps.

The invention also relates to the manufacturing of high efficiency solar cells at reduced manufacturing costs. The invention concerns in particular the manufacturing of interdigitated back contact (IBC) solar cells.

### BACKGROUND INFORMATION AND PRIOR ART

Numerous documents describe devices and methods for the manufacture of devices incorporating patterned thin film and in particular solar cell devices.

The steps of thin film deposition and/or etching can be realized by different techniques and in particular by plasma enhanced chemical vapour deposition (PECVD) in general at low temperatures (less than 300° C.).

In microelectronics, the patterning step is generally based on photolithography to generate patterned thin films with sub-micrometric critical dimensions (CD) and with very high aspect ratios. However, photolithography requires additional materials, processing steps and expensive tools, such as a stepper, and thus induces large manufacturing costs. Much lower resolution techniques may be used, but these also involve multiple masking and etching steps.

Laser ablation can also be used for forming holes in a thin film stack without involving masking. However, laser processing is also expensive.

High efficiency industrial crystalline silicon (c-Si) solar cells use localized contacts to reduce the surface area in contact with metal or to reduce shading by metallic gridlines.

The highest efficiency industrial c-Si cells use an interdigitated back contact (IBC) configuration, but this is an expensive design to implement, involving more process steps: laser ablation for forming dielectric openings for point contacts or lithography for forming the IBC contacts. Nevertheless, IBC designs and point contacts are currently used in industry, as described by R. Swanson et al. (Proceeding of the 33rd IEEE PVSC, San Diego, Calif., USA, 2008).

Another industrial high-efficiency design (HIT technology) uses a thin intrinsic amorphous hydrogenated silicon (a-Si:H) layer, deposited by PECVD, as the passivating layer. HIT passivation is advantageously realized at low temperature (less than about 250° C.) thus reducing the thermal budget of the process, and resulting in very good passivation properties for the wafer surface.

Panasonic (Masuko et al, IEEE Journal of Photovoltaics 4 (2014) 1433-1435) has recently demonstrated an IBC solar cell design using large area HIT passivation. However, using a thin intrinsic a-Si:H passivation layer in an IBC configuration involves a subsequent patterning step for the doped layers, using photolithography, thus reducing the cost effectiveness of the low temperature HIT passivation.

One of the challenges in implementing a masking operation on the pristine surface of a silicon wafer (with oxide removed) is the high sensitivity of this surface to damage and contamination.

### SUMMARY OF THE INVENTION

Therefore one object of the invention is to provide an apparatus and a method for forming devices having a patterned structure, such as a patterned surface or patterned layers, especially for high-efficiency solar cell applications or semiconducting devices or optoelectronic devices, at a reduced manufacturing cost and preferably at low temperature.

A further object of the invention is to provide an alternative apparatus and method for forming interdigitated contacts in IBC solar cells and/or for forming dielectric openings for point contacts in solar cells.

A further object of the invention is to provide a fully integrated method and apparatus enabling both surface passivation and patterning in a single processing flow step and/or in a single processing tool chamber, so as to prevent surface damage, contamination, and avoiding additional tool-related capital cost.

The above objects are achieved according to the invention by providing a plasma generating apparatus for manufacturing devices having a patterned layer or surface, the plasma generating apparatus comprising a plasma reactor chamber, a gas feed assembly for introducing an input gas into the plasma reactor chamber at a chosen pressure, a first electrode assembly and a second electrode assembly placed in the plasma reactor chamber, the first electrode assembly being spaced apart from the second electrode assembly by an inter-electrode volume and an electrical power supply for generating a time-varying or a constant voltage difference V(t) between the first electrode assembly and the second electrode assembly.

According to the invention, the first electrode assembly comprises a plurality of protrusions and a plurality of recesses, the second electrode assembly being configured for receiving a substrate having a surface facing the plurality of protrusions and the plurality of recesses, the protrusions and recesses being dimensioned and set at respective distances from the surface of the substrate so as to generate a plurality of spatially isolated plasma zones located selectively either between said surface of the substrate and said plurality of recesses or between said surface of the substrate and said plurality of protrusions at the chosen pressure of the input gas.

The plasma generating apparatus thus enables to perform plasma processing on the surface of the substrate on areas defining a pattern which is roughly delimited by the protrusions and recesses, so as to form a pattern on the surface of the substrate.

The invention enables spatially selective deposition of patterned layer(s) using plasma enhanced chemical vapour deposition, without touching the substrate surface. Depending on the plasma conditions, and in particular on the chemical composition of the input gas, the invention also enables spatially selective etching of the surface of the substrate, thus forming a patterned surface with openings, using plasma enhanced chemical vapour etching without touching the substrate surface. In other words the invention achieves a masking operation without applying a mask on the surface of the substrate.

The present disclosure is based on shaping the powered first electrode assembly, thus using geometrical dimensions of the first electrode assembly as well as shadowing effects to limit laterally the ignition of the plasma to well-defined volumes. This allows a rough masking operation to be implemented. Furthermore, multiple patterns can be implemented by changing the electrode configuration in real time. Furthermore, a uniform, maskless deposition, or etching process can be done in the same plasma reactor chamber by backing the electrode away from the surface of the substrate, so that the plasma ignition is not limited laterally by the protrusions and recesses but extends over the interelectrode volume.

According to a particular regime of operation, for a given optimal applied voltage difference V(t), which may be a constant DC potential or a time varying voltage difference ideally with frequency components in the radio-frequency range (500 kHz to 100 MHz), the recesses are dimensioned to be placed at a second distance from the surface of the substrate such that, for the applied voltage difference V(t), a product of the chosen pressure and the second distance is comprised between a first plasma ignition threshold and a second plasma extinction threshold (thus ensuring local plasma ignition between the recesses and the surface of the substrate), and the protrusions are dimensioned to be placed at a first distance from the surface of the substrate such that, for the applied voltage difference V(t), another product of the chosen pressure and the first distance is lower than the first plasma ignition threshold (thus ensuring no plasma ignition between the protrusions and the surface of the substrate), such that the plasma generating apparatus generates spatially isolated plasma zones between the surface of the substrate and the recesses without generating plasma locally between the surface of the substrate and the protrusions.

According to a particular aspect of the invention, for a given optimal applied voltage difference V(t), which may be a constant DC potential or a time varying one ideally with frequency components in the radio-frequency range (500 kHz to 100 MHz), the protrusions are dimensioned to be placed at a first distance from the surface of the substrate such that, for the applied voltage difference V(t), the product of the pressure and the first distance is comprised between a first plasma ignition threshold and a second plasma extinction threshold (thus ensuring local plasma ignition between the protrusions and the surface of the substrate), and the recesses are dimensioned to be placed at a second distance from the surface of the substrate such that, for the applied voltage difference V(t), another product of the chosen pressure and the second distance is larger than a second plasma extinction threshold (ensuring no plasma ignition locally between the recesses and the surface of the substrate), such that the plasma generating apparatus generates spatially isolated plasma zones between the surface of the substrate and the protrusions without generating plasma locally between the surface of the substrate and the recesses.

According to still another regime of operation, the first electrode assembly comprises a plurality of protrusions of rectangular profile placed at a first distance from the surface of the substrate and a plurality of recesses of rectangular profile having bottoms at a second distance from the surface of the substrate.

According to a particular embodiment of the invention, the first electrode assembly comprises at least a first and a second part, the first part being mobile relatively to the second part between a first position and a second position, such that, in the first position said first electrode assembly forms a plurality of protrusions and a plurality of recesses, and, in the second position, the first electrode assembly forms a flat surface facing the surface of the substrate.

According to another embodiment of the invention, the plurality of recesses comprises a plurality of cavities, each cavity being connected to the inter-electrode volume by a channel, the cavities being dimensioned such that the apparatus generates plasma within said cavities at the chosen pressure, and the channels being dimensioned such that the plasma generated in the cavities diffuses toward the inter-electrode volume.

According to a particular aspect of this embodiment, the plurality of recesses or a subset of the plurality of recesses is connected to a common cavity, the common cavity being connected to at least one gas inlet and to at least one gas outlet, so as to ensure optimal gas flow conditions.

According to particular aspects of this embodiment, said cavity has a square, rectangular, spherical or conic profile and/or the channels have a cross-section shape chosen among a rectangular, trapezoidal, conical or cylindrical shape, or a shape chosen to generate a pattern with determined spatial profile on the surface of the substrate. Optionally, the channels being interconnected to a common cavity, the channels of the interconnected channels have respective gas inlets and/or gas outlets with determined shapes so as to form patterned features with determined profile shape.

According to a particular embodiment, the first electrode assembly comprises at least a first and a second sub-sets of recesses, the first sub-set of recesses being electrically isolated from the second sub-set of recesses, and the first electrode assembly comprises a first and a second sub-electrodes, the first, respectively second, sub-electrode electrically connecting the first, respectively second, sub-set of recesses, and the electrical power supply is configured for generating a first, respectively a second, voltage difference between the first, respectively second, sub-electrodes and the second electrode assembly.

According to a particular aspect, the first electrode assembly comprises at least a first and a second sub-sets of recesses, and the gas feed assembly comprises a first and a second input gas lines, the first, respectively second, gas line being in fluidic communication with the first, respectively second, sub-set of recesses, so as to inject a first, respectively second, input gas into the first, respectively second, sub-set of recesses.

According to a particular and advantageous aspect of the invention, the plurality of protrusions and the plurality of recesses are arranged in a one-dimension or two-dimension periodic array.

According to another particular and advantageous aspect of the invention, the first electrode assembly and/or the second electrode assembly is/are mounted on a translation or rotating stage.

According to another embodiment of the invention, the plasma generating apparatus comprises an electric source configured for generating a voltage difference to be applied between the first and second electrode, wherein the voltage difference is constant over time, or comprises a single base frequency in the range between 500 kHz and 100 MHz or comprises a plurality of harmonics of a base frequency in the range between 500 kHz and 100 MHz, and wherein the respective amplitudes and phases of the plurality of harmonics are selected so as to generate voltage difference having waveform with an amplitude asymmetry (for example resembling a series of peaks or valleys) or with a slope asymmetry (for example resembling a sawtooth voltage waveform).

The invention also concerns a method of manufacturing patterned devices using spatially resolved plasma processing comprising the steps of:
Placing a substrate in a plasma reactor chamber of a plasma generating apparatus, the substrate being in contact with a second electrode assembly and having a surface facing a first electrode assembly comprising a plurality of protrusions and a plurality of recesses;
Injecting an input gas or gas mixture into the plasma reactor chamber under a chosen pressure;
Configuring the first electrode assembly such that the protrusions are at a first distance and the recesses are at a second maximum distance from the surface of the substrate,
Applying a DC or radio-frequency voltage difference between the first electrode assembly and the second electrode assembly, the protrusions and recesses being dimensioned and set at respective distances from the surface of the substrate so as to generate a plurality of spatially isolated plasma zones located selectively either between the surface of the substrate and the plurality of recesses or between the surface of the substrate and the plurality of protrusions at the chosen pressure of the input gas, so as to form by deposition or etching a pattern on the surface of the substrate.

According to a particular and advantageous aspect, the method of manufacturing patterned devices further comprises a step of moving the first electrode assembly relatively to the second electrode assembly so as to modify the first distance, and/or respectively the second distance, such that the product of the chosen pressure and the first distance, and respectively the product of the chosen pressure and the second distance, are both comprised between a first plasma ignition threshold and a second plasma extinction threshold, so as to generate a spatially uniform plasma zone extending over the inter-electrode volume.

According to another particular and advantageous aspect, the method of manufacturing patterned devices further comprises the steps of:
electrically isolating a first sub-set of recesses from a second sub-set of recesses of the first electrode assembly; and
applying a first, respectively, second, voltage difference between the second electrode assembly and the first respectively, second, sub-set of recesses.

According to another particular and advantageous aspect, the method of manufacturing patterned devices further comprises the steps of:
Fluidic connection of a first, respectively second, gas line to a first, respectively second, sub-set of recesses of the first electrode assembly; and
Injecting a first, respectively second, input gas into the first, respectively second, sub-set of recesses, and/or
Providing a first, respectively second, gas flow outlet connected the first, respectively second, sub-set of recesses, to prevent mixing of gas composition and achieve different deposition/etching processes under the first and second sub-set of recesses.

According to another particular and advantageous aspect, the method of manufacturing patterned devices further comprises, prior to step a):

an initial step of depositing an homogeneous layer on the surface of the substrate intended to be facing the first electrode assembly at step a), and wherein the input gas or gas mixture injected at step b) is selected so that the spatially isolated plasma zones generated at step d) produce spatially selective etching of the homogeneous layer so as to form a patterned layer by etching openings in the homogeneous layer.

According to another particular and advantageous aspect, the method of manufacturing patterned devices further comprises, after step d):
i) another step of depositing another homogeneous layer on the openings and on the patterned layer;
j) applying another series of steps a, b), c) and d) wherein the input gas or gas mixture injected at said another step b) is selected so that the spatially isolated plasma zones generated at said another step d) produce spatially selective etching of said another homogeneous layer on the patterned layer and so as to form another patterned layer in the openings of the patterned layer.

According to another particular and advantageous aspect, the method of manufacturing patterned devices further comprises, after step d):
k) applying another series of steps a, b), c) and d) wherein the input gas or gas mixture injected at said another step b) is selected so that the spatially isolated plasma zones generated at said another step d) produce spatially selective deposition of another patterned layer in the openings of the patterned layer.

The invention applies in particular to the manufacture of photovoltaic solar cell devices in a plasma generating apparatus and/or using a method of manufacturing patterned devices as disclosed herein.

### BRIEF DESCRIPTION OF THE DRAWINGS

This description is given for non limiting illustrative purposes only and will be better understood when referring to the annexed drawings wherein:

FIG. 1 represents schematically a cross-section of a plasma processing apparatus according to a first embodiment, in a first operating regime;

FIG. 2 represents schematically a cross-section of the first embodiment of a plasma processing apparatus, in another operating regime;

FIG. 3 represents schematically a breakdown voltage curve for a plasma processing apparatus as a function of the product of input gas pressure by electrode separation, commonly referred to as the Paschen curve;

FIGS. 4A-4B represent schematically a cross-section of a variant of the first embodiment of a plasma processing apparatus, with a two-part electrode;

FIGS. 5A-5C represent schematically an example of different steps for the manufacture of patterned devices using spatially resolved plasma according to an embodiment of the invention;

FIG. 6 illustrates schematically Interdigitated electrodes obtained from the exemplary process of FIG. 5;

FIGS. 7A-7B illustrate examples of forming point contacts using spatially resolved plasma processing according to various embodiments of the invention;

FIG. 8 represents schematically a cross-section of a second embodiment of a plasma processing apparatus;

FIG. 9 represents schematically a cross-section of a variant of electrode design according to the second embodiment of a plasma processing apparatus;

FIG. 10 represents schematically cross-section of various cavities according to the second embodiment of a plasma processing apparatus;

FIG. 11 represents schematically in cross-section still another variant of configuration of gas injection wherein the channels are connected to a common cavity;

FIG. 12 represents schematically in cross-section another variant of electrode configuration according to an embodiment of the invention;

FIG. 13 represents schematically in cross-section still another variant of configuration of gas injection according to another embodiment of the invention;

FIG. 14 represents schematically in cross-section still another variant of applied voltage difference of various waveforms configured for adjusting the proximity of the plasma area relatively to the surface of the sample;

FIG. 15 illustrates an example of a processing tool and method for depositing a homogeneous layer on a substrate;

FIG. 16 illustrates an example of a processing tool and method to achieve selective plasma etching of the homogeneous layer deposited in FIG. 15;

FIG. 17 shows an example process flow to deposit n-type and p-type fingers for IBC solar cells;

FIG. 18 shows an alternative example process flow to deposit n-type and p-type fingers for IBC solar cells.

### DETAILED DESCRIPTION OF EXAMPLE(S)

The present disclosure concerns a technique to perform contactless masking of a plasma process, such as PECVD deposition or etching, by restricting spatially, and more precisely laterally, the area of plasma ignition.

In an embodiment this is achieved through a powered electrode design for a radio-frequency-PECVD system, operating in a first regime, generally at low pressure (<10 Torr), wherein the ignition of the plasma close to the protrusion of the first electrode assembly is inhibited by the first electrode assembly-substrate distance being less than the sheath width of the plasma used for deposition.

In various embodiments, channels or holes in the electrode determine where the plasma lights in the first operating regime, where a small distance prevents plasma ignition at low pressure.

In another operating regime, generally at high pressure (>10 Torr), the ignition of the plasma of the first electrode assembly is enabled close to the protrusion and inhibited close to the recesses by the first electrode assembly-substrate distance being too large for sustaining a plasma in the recesses, under the chosen pressure and voltage conditions used for the plasma.

The spatially selective ignition of the plasma allows one to deposit or etch thin-films in predetermined areas without contacting the surface, thus achieving contactless masking. The critical dimensions and feature sizes of the patterned layers obtained by this technique are in the sub-millimeter range (from one to several hundreds of micrometers) and are consistent with those required for the fabrication of interdigitated back contacts (IBC) solar cells or point contact openings for solar cells.

Device

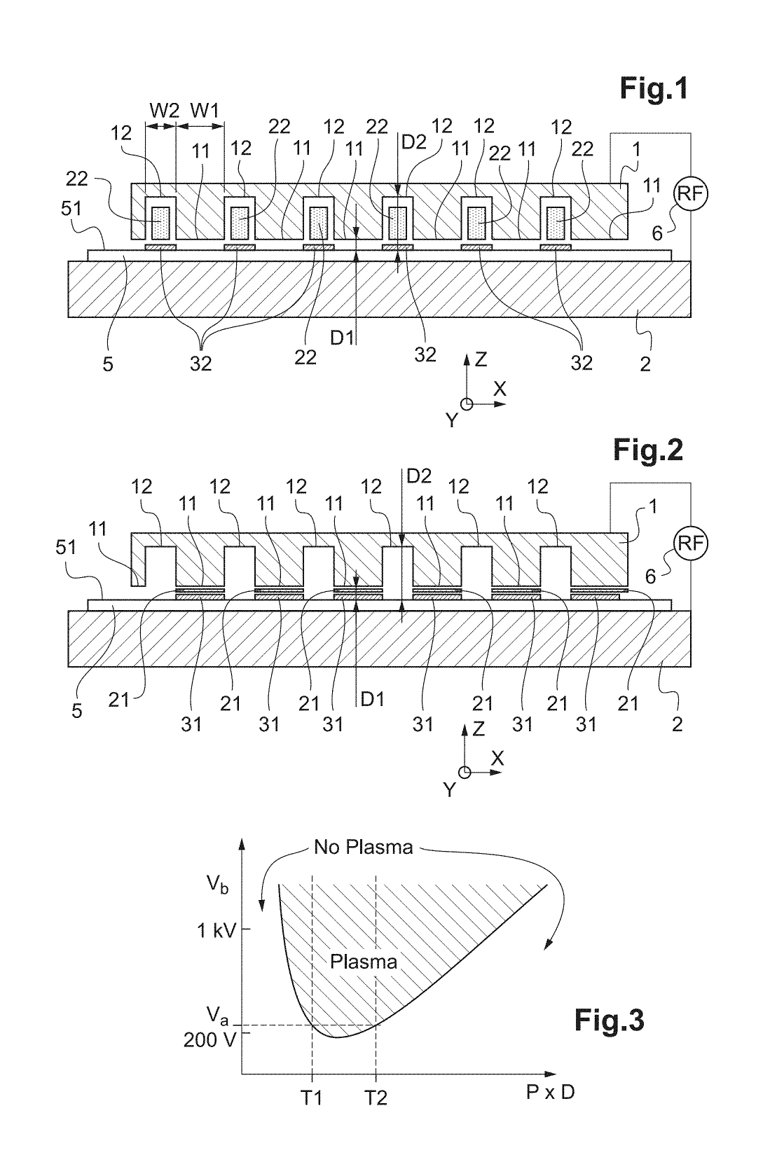

FIG. 1 represents schematically a cross-section of a plasma processing apparatus according to a first embodiment of the invention, and operating in a first regime. Generally, the plasma processing apparatus comprises a vacuum chamber in fluidic connection with a pressured gas line for injecting an input gas and a vacuum pumping system for evacuating output gas. The vacuum chamber encloses a substrate holder and an electrode system for powering the plasma inside the reaction chamber.

More specifically, we consider the representative case of a radio-frequency (RF) capacitively coupled plasma reactor comprising a first electrode assembly 1 and a second electrode assembly 2. An RF power supply 6 is electrically connected to the first and second electrode assemblies 1, 2, so as to apply an RF voltage difference between the first and second electrode assemblies. In this example, the second electrode assembly 2 is electrically connected to ground, so that the first electrode assembly 1 is the powered electrode.

A substrate 5 is placed on the second electrode assembly 2 so that a surface 51 of the substrate 5 faces the first electrode assembly 1. The substrate is for example a semiconductor such as monocrystalline or polycrystalline silicon or a glass substrate. Alternatively, the substrate 5 may comprise a thin film stack forming the surface 51. The surface 51 of the substrate 5 may be flat or may be a patterned surface.

In the example of FIG. 1, the second electrode assembly 2 is flat, as in a conventional capacitively coupled plasma reactor. In contrast, in this first embodiment, the first electrode assembly 1 comprises a plurality of recesses 12 separated from each other or surrounded by protrusions 11. In the example of FIG. 1, the protrusions 11 and the recesses 12 have a rectangular shape, having a width W1, respectively W2 along an axis X parallel to the surface of the substrate. The protrusions 11 are at a first distance D1 from the surface 51 of the substrate, and the recesses 12 are at a second distance D2 from the surface 51 of the substrate. The gas injection system (not represented on FIG. 1) is configured so that the input gas fills the inter-electrode volume between the first and second electrode assemblies and thus fills the recesses 12.

More precisely, in a first regime illustrated in FIG. 1, the first distance D1 is adjusted so that, at the applied voltage and at the chosen pressure P of the input gas in the plasma reactor chamber, the first distance D1 is lower than a first threshold value corresponding to a plasma ignition threshold. This first regime is generally operated at low pressure (<10 Torr). As an example of first regime operating conditions, the input gas is a mixture of at minima a deposition precursor gas (such as SiH₄) or an etching gas (such as SF₆) and possibly a second buffer gas (such as H₂) at a pressure between 0.1 and 10 Torr, the width W1 is between 0.75 mm and 2 mm, the first distance D1 is set to between 0.1 and 1.0 mm, so that this first distance D1 is too small for plasma ignition between the protrusions 11 and the surface 51 of the sample 5 for the chosen applied RF voltage, with an amplitude between 200V and 800V.

However, in this first regime, the recesses 12 are dimensioned so that the second distance D2 is above the first threshold value corresponding to a plasma ignition threshold. Thus, several localized plasmas 22 ignite within the recesses 12 and extend in front of the recesses 12 up to the surface 51 of the substrate 5. However, the protrusions 11 provide a quenching effect preventing the localized plasma zones 22 to merge into an extended plasma. Thus, the localized plasma areas 22 remain confined into spatially isolated spaces between the recesses 12 and the surface 51 of the substrate 5. As an example of first regime, the width W2 of the recesses 12 is between 0.1 mm and 5 mm, the second distance D2 is set to at least 2 mm, the width W1 of the protrusions 11 being at least of 0.1 mm.

This first regime enables for example local deposition of a patterned layer 32 by PECVD, the lateral dimension of the patterned thin layer 32 along the axis X being determined mainly by the widths W1 of the protrusions 11 and by the widths W2 of the recesses 12.

The recesses 12 may have a one-dimensional geometry and extend along the Y axis with a similar profile, for generating patterns extending longitudinally on the surface of the sample along the Y-axis.

Alternatively, the recesses 12 may have a two-dimension geometry and for example, have a similar profile as illustrated in FIG. 1 along the Y axis, for generating patterns limited in both the X and Y directions on the surface 51 of the sample 5.

Of course, more complex geometries of protrusions 11 and recesses 12 are also contemplated without departing from the frame of the present disclosure.

The relative proportion of deposited areas patterned layer 32 versus non-deposited areas in the example of FIG. 1 would be consistent with an application of leaving an area to deposit another layer in between the patterned layer 32, for example, for the creation of interdigitated contacts.

By increasing the width W2 of the recesses 12 and relatively decreasing the width W1 of the protrusions 11, as well as establishing these recesses in two dimensions, enables one to deposit continuous films with small holes. If such films are formed from a dielectric material, such a configuration could be used to implement for example point contacts.

FIG. 2 represents schematically a cross-section of the first embodiment of plasma processing apparatus operating in a second regime. The same reference numbers refer to the same elements as represented on FIG. 1. In this second regime, the first distance D1 is adjusted so that, for a given applied voltage difference and at a chosen pressure P of the input gas in the plasma reactor chamber, generally at relatively high pressure (>10 Torr), the first distance D1 is higher than a first threshold value corresponding to a plasma ignition threshold. Thus, in the second regime, localized plasmas 21 ignite between the protrusions 11 and the surface 51 of the substrate 5. At the same time, the recesses 12 are located at a second distance D2 which is above a second threshold value corresponding to a plasma extinction threshold. The recesses 12 are dimensioned so that a quenching effect prevents the localized plasma zones 21 to extend into the recesses. Thus, the localized plasma areas 21 remain confined into spatially isolated spaces between the protrusions 11 and the surface 51 of the substrate 5.

As an example of the second regime, the input gas mixture is at minima composed of a deposition precursor gas (such as SiH₄) or an etching gas (such as SF₆), and possibly a buffer gas (such as He) at a pressure of between 10 to 100 Torr, the applied voltage is between 100V and 1 kV, the first distance D1 is set to between 0.1 and 1 mm, so that this first distance D1 is high enough for plasma ignition between the protrusions 11 and the surface 51 of the sample 5, and the second distance D2 is set to 2 to 10 mm so that the second distance D2 is too high for plasma ignition in the recesses 12.

In the second regime, where the pressure combined with a large distance limits ignition (usually high pressure), protrusions 11 from the surface of the electrode determine the pattern 31 that is deposited, resulting in a complementary or negative image of the positive pattern layer 32 deposited in the first regime, with a same first electrode assembly.

FIG. 3 helps to explain the different operating regimes set forth in the invention. FIG. 3 represents schematically a breakdown voltage curve Vb of a plasma processing apparatus as a function of the product of input gas pressure P and the electrode separation D for a capacitively coupled RF plasma reactor or a directly coupled DC plasma reactor, commonly called the Paschen curve. The breakdown voltage Vb is defined as the minimum voltage to be applied between electrodes for plasma ignition as a function of the pressure P, for a given interelectrode distance D or as a function of the interelectrode distance D, for a given pressure P.

For processing plasmas, the range of pressure P is generally comprised between a few milliTorrs and several tens of Torrs, or less than 100 Torr.

We consider an RF voltage amplitude Va applied to the first electrode assembly 1, this RF voltage amplitude Va being higher than the minimum value of the breakdown voltage curve. The intersection of this applied voltage Va with the breakdown voltage curve defines a first threshold value T1 and a second threshold T2.

First, we consider the area of the graph where the product PxD of pressure P by the interelectrode distance D is below the first threshold value T1: in these conditions, there is no plasma ignition. Or, in other words, for a chosen pressure P and chosen RF voltage amplitude Va, if the electrode separation D is below a first threshold distance, there is no plasma ignition since the applied voltage Va is lower than the breakdown voltage Vb curve. Next, we consider the area of the graph where the product PxD is above the first threshold value T1 and below the second threshold value T2: in these conditions, there is plasma ignition because the voltage applied Va to the electrodes is higher than the breakdown voltage Vb curve. Or, in other words, for a chosen pressure P and a chosen applied voltage Va, if the electrode separation D is higher than the first threshold distance and below a second threshold distance, plasma ignition occurs. Finally, we consider the area of the graph where the product PxD is above the second threshold value T2: in these conditions, there is no plasma since the applied voltage Va is lower than the breakdown voltage Vb curve. Or, in other words, for a chosen pressure P and a chosen applied voltage Va, if the electrode separation D is higher than the second threshold distance, there is no plasma ignition. The first operating regime of the plasma generating apparatus according to the first embodiment of the invention, as illustrated in FIG. 1, corresponds to the conditions where the first distance D1 is smaller than a first threshold distance T1/P as determined on FIG. 3 for a given pressure P and applied voltage Va, and where the second distance D2 is between a first and a second threshold distances [T1/P; T2/P], for the same pressure P and applied voltage Va.

In contrast, the second operating regime of the plasma generating apparatus according to the first embodiment of the invention, as illustrated in FIG. 2, corresponds to the conditions where the first distance D1 is between the first and the second threshold distances, and where the second distance D2 is larger than the second threshold distance, as determined in FIG. 3. Or, for given distances D1 and D2, the pressure P is increased so that the product PxD1 is comprised between T1 and T2, and the product PxD2 is larger than T2.

Additionally, in a third regime, when both the first and second distances D1 and D2 are increased and/or when the pressure P is increased, so that both products PxD1 and PxD2 are situated between the first threshold T1 and the second threshold T2, the plasma ignites over the whole first electrode assembly, so that the plasma areas 22 within the recesses 12 merge with the plasma areas 21 facing the protrusions, thus forming a single extended plasma area.

Alternatively or complementarily to the change in distance between the first electrode assembly 1 and the surface of the substrate, those skilled in the art will recognize that the three different regimes described above can be obtained by controlling the input pressure P and/or the applied voltage Va. This technique, however, is limited by the process condition limits necessary to achieve the desired steps, in particular passivation of a surface or deposition of high-quality doped layers.

However, for the sake of clarity of the present disclosure, we make the assumption that the applied voltage Va and input gas pressure P are maintained constant, and that the distance between the first electrode assembly 1 and the surface of the substrate is controlled for operating in the appropriate regime.

It is to be observed that, until now, plasma processing apparatuses are generally operated in the conditions where a single plasma area forms between the first electrode assembly and the surface of the substrate, because processing uniformity is usually a strong requirement, either for deposition or for etching. Even in previous hollow cathode-type plasma generating systems, a single plasma area is formed below the plurality of hollows within the cathode, ensuring the uniform processing of a large area substrate. On the contrary, the present disclosure takes advantage of a plurality of laterally localized and isolated plasma areas 21, or 22, to perform localized plasma treatment on the surface 51 of the substrate 5, so as to enable spatially resolved thin film deposition or etching, and thus pattern deposition. By analogy with photolithography, this plasma processing technique may be called plasma-lithography as it enables one to deposit patterned thin films with determined critical dimensions (CD) and aspect ratios (AR).

A major advantage of the plasma-lithography technique is to enable direct deposition of a patterned thin film, without using a mask, thus avoiding the multiple processing steps associated with lithography, including photolithography, and avoiding any deleterious effects of the contact of a mask with the substrate surface.

Thus, plasma-lithography as disclosed herein enables drastic reduction in processing costs for the manufacture of patterned layers or devices.

In terms of performance, plasma-lithography enables one to form patterns with sub-millimeter critical dimensions, down to about a hundred micrometers along an axis X and/or Y. Such critical dimensions are well-suited for current requirements in industrial solar cell manufacturing.

The first electrode assembly can be formed from a single conductive part. For example, the recesses 12 are machined as holes or slits in a bulk metallic plate.

Alternatively, the first electrode assembly 1 comprises an assembly of parts attached to each other. In a variant alternative, the first electrode assembly 1 comprises several parts, at least one of the parts being mobile relatively to the other(s).

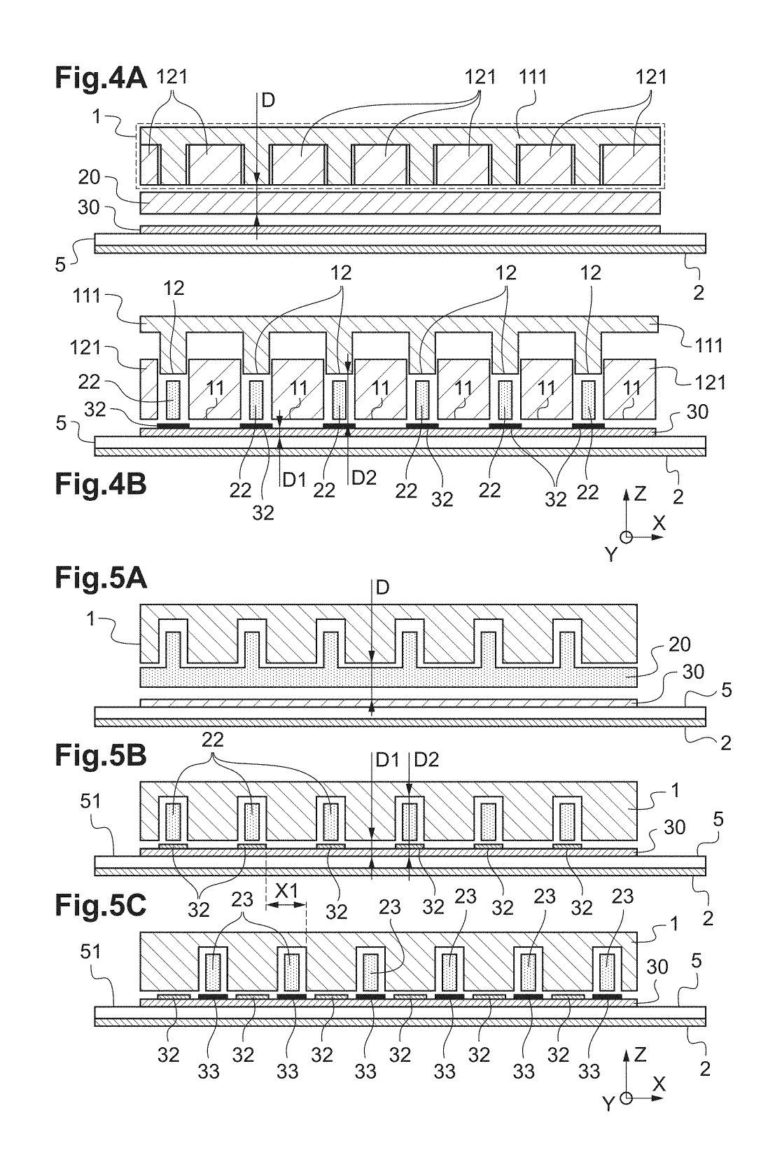

As an example FIG. 4 represents schematically a cross-section of a variant of the first embodiment of a plasma processing apparatus, with the first electrode assembly 1 in two parts. More precisely, the first electrode assembly 1 comprises a first part 111 and a second part 121. Preferably, the first part 111 and second part 121 have complementary shapes, such as a comb for example. On FIG. 4A, the first part 111 and second part 121 are fitted so that the first electrode assembly 1 forms a flat surface at a distance D from the surface 51 of the substrate 5. The pressure P, distance D and applied voltage are adjusted so as to generate a plasma 20 between the first electrode assembly 1 and the surface 51 of the substrate 5. This first configuration enables for example deposition of a layer 30 having a uniform thickness (or non patterned) on the surface 51 of the substrate 5. For example, this configuration may be used for depositing a passivation layer of intrinsic amorphous hydrogenated silicon (i) a-Si:H. As an option, by changing the input gas, this first configuration of FIG. 4A may also be used for cleaning or removing an oxide layer from the surface 51 of the substrate 5 before deposition of the i-layer 30.

In a second position, illustrated FIG. 4B, the second part 121 is translated along the Z axis in the direction of the sample surface 51 while the first part 111 remains fixed, so as to form recesses 12 and protrusions 11. In the example illustrated FIG. 4B, the second part is drawn near the substrate surface 51 so that the protrusions 11 are at a distance D1 from the substrate surface 51 and so that the bottoms of the recesses 12 are at a distance D2 from the substrate surface 51. In the second position, the plasma generating apparatus is operated in pressure and voltage conditions so that a local plasma areas 22 ignite between the surface 51 of the substrate 5 and the recesses 12 and the protrusions 11 provide a shadowing effect preventing plasma ignition between the protrusions 11 and the surface 51 of the substrate 5, similarly as described in relation with FIG. 1. Alternatively, the plasma generating apparatus with a two-part first electrode assembly can be operated in pressure and voltage conditions similar to those described in relation with FIG. 2.

The patterned deposited layers may have a thickness of 5 nanometers to several hundred of nanometers, with sub-millimeter critical dimensions.

Process

We will now describe FIGS. 5A-5C an example of integrated process using a plasma generating apparatus according to the first embodiment of the invention.

In FIG. 5A, the plasma generating apparatus operates in the third regime, the first electrode assembly 1 being placed at a distance and the pressure P being adjusted, so that both products PxD1 and PxD2 are situated between the first threshold T1 and the second threshold T2, and the plasma 20 ignites over the whole volume between the first electrode assembly and the substrate surface 51. This step is for example used for depositing a passivation layer of intrinsic amorphous hydrogenated silicon (i-layer) or for the removal of a native oxide layer.

In FIG. 5B, the plasma generating apparatus operates in the first regime, the first electrode assembly 1 being placed at a distance D1 and/or the pressure P being adjusted, so that the product PxD1 is lower than the first threshold T1 and the product PxD2 is between the first threshold T1 and the second threshold T2. For example, the first electrode assembly 1 is drawn near the substrate surface 51, so that localized plasma areas 22 ignite between the recesses 12 and surface 51 of the substrate 5, while the protrusions 11 prevent local plasma ignition between the protrusions 11 and the surface 51 of the substrate 5. This second step may be used for depositing a n-doped patterned layer 32 using the appropriate input gas mixture, such as a mixture of H₂, SiH₄, and PH₃.

In FIG. 5C, the first electrode assembly 1 is rotated and/or translated by a distance X1 relatively to the sample surface 51, so as to align the recesses 12 in between the patterned layer 32 deposited at the previous step. The input gas is switched so as to deposit another patterned layer, ideally in this example a p-doped layer, from a gas mixture composed of H₂, SiH₄, and B₂H₆. For example, the movement of the first electrode assembly 1 is of about 0.5-2 mm with sub-millimeter precision. The plasma generating apparatus operates again in the first regime, the first electrode assembly 1 being placed at a distance and the pressure P being adjusted, so that the product PxD1 is lower than the first threshold T1 and the product PxD2 is between the first threshold T1 and the second threshold T2, so that localized plasma areas 23 ignite between the recesses 12 and surface 51 of the substrate 5, while the protrusions 11 prevent local plasma ignition between the protrusions 11 and the surface 51 of the substrate 5. This second step may be used for depositing a p-doped patterned layer 33. Equivalently, the rotation or translation may be implemented by the second electrode assembly or simply the substrate, whichever is most suitable for the practical implementation of the relative motion.

The steps illustrated on FIGS. 5A-5C can be repeated with as many movable parts and steps as desired. The n-layer pattern and the p-layer pattern may or may not be identical. The process flow of FIG. 5 enables the deposition of the passivating layer and of patterned layers with two different doping levels. This process finds application for example to the manufacture of IBC solar cells, in a single process flow, and in a single reactor chamber, at the expense of a relative movement between the first electrode assembly 1 and the substrate surface 51.

The first electrode assembly and processing conditions enable deposition of multiple patterned and/or non-patterned layers in sequential process steps.

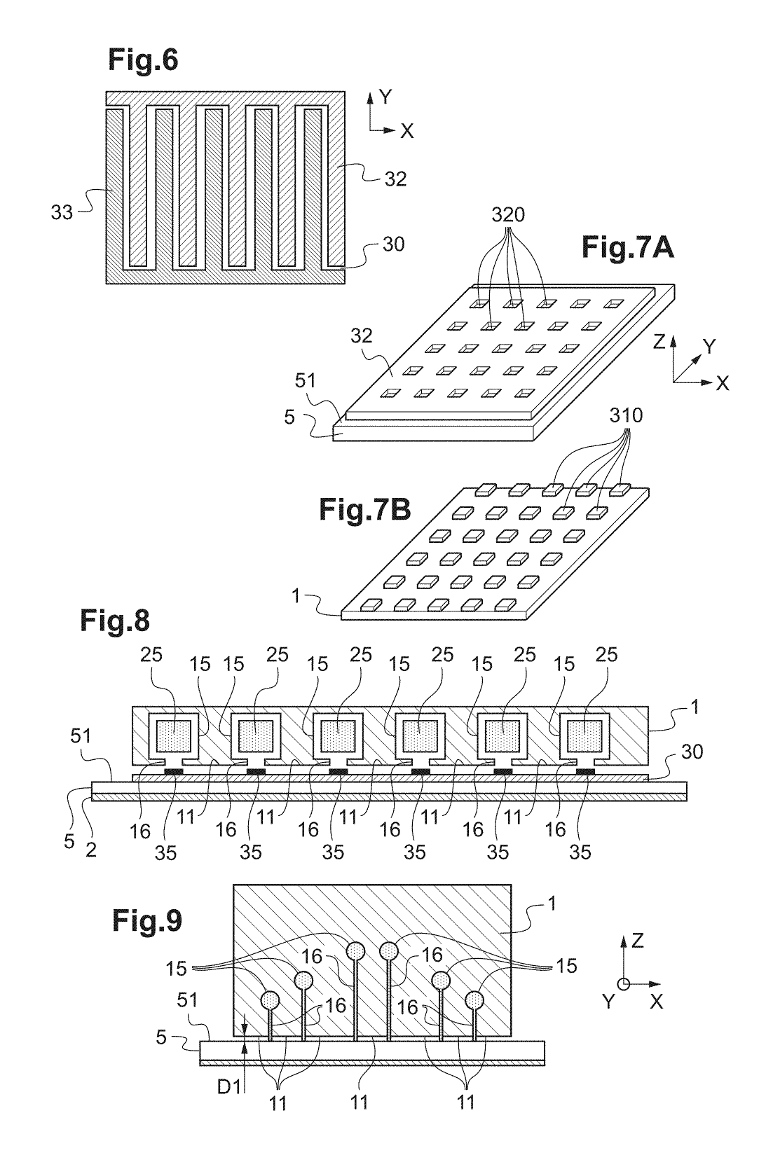

FIG. 6 shows a top view of an exemplary patterned device as obtained by a process and plasma generating apparatus as described above. The patterned device comprises a uniform passivating i-layer 30, a n-doped patterned layer 32 and a p-doped patterned layer 33. The passivation layer 30 covers the whole surface of the substrate 5.

FIG. 7A shows another exemplary patterned device obtained by applying spatially resolved plasma etching for forming openings 320 in a dielectric layer 32 on the surface 51 of a sample 5. This patterned structure may be realized in two steps: step 1—uniform deposition of a dielectric layer, and step 2—spatially resolved plasma etching. Optionally, these two steps are performed in a same process flow and/or in a in a single reactor chamber.

FIG. 7B shows the exemplary powered electrode design comprising protrusions 310 required to achieve the pattern (displayed in FIG. 7A) of openings 320 on the surface 51 of a sample 5. This patterned structure illustrated on FIG. 7A may be realized in a single step using the electrode design represented on FIG. 7B.

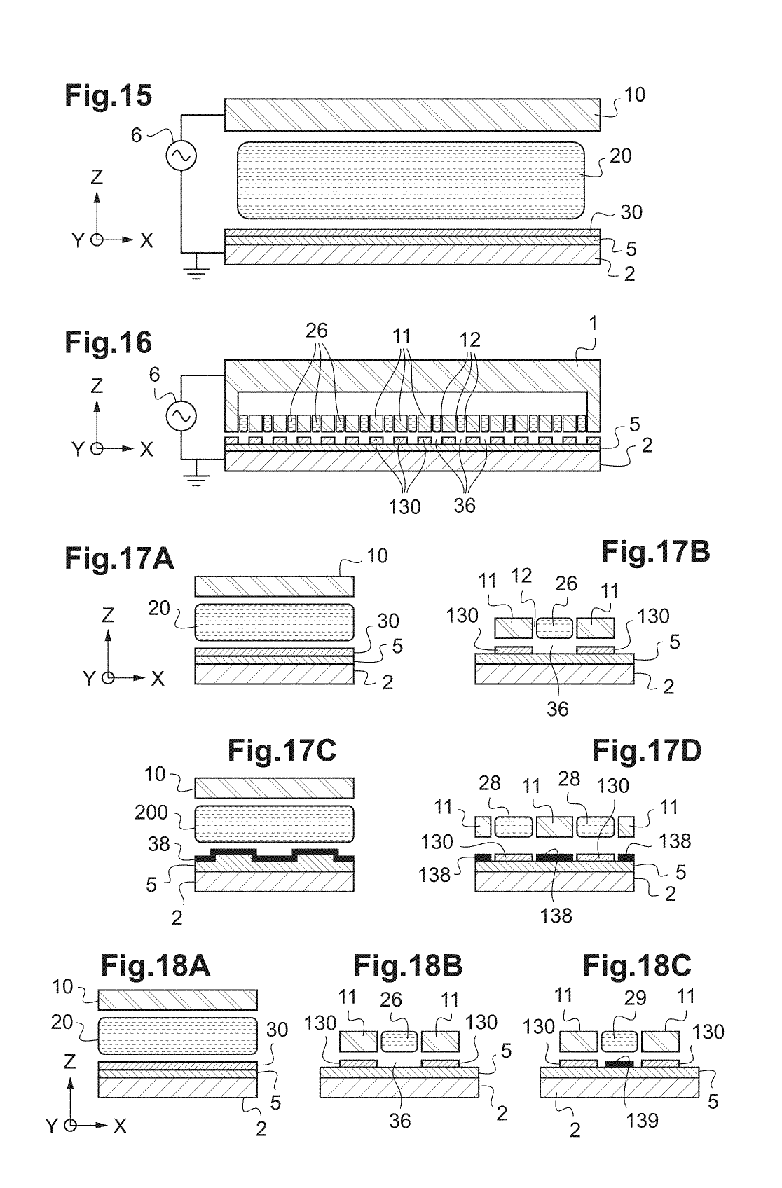

FIGS. 15 and 16 schematically show a processing apparatus and method according to a particular embodiment. This method comprises at least a first step of uniform deposition of a at least one layer on a substrate and a second step of spatially resolved plasma etching so as to produce an etched pattern in the uniformly deposited layer.

FIG. 15 illustrates an example of a processing tool and method to achieve the first step of uniform deposition. FIG. 15 represents a conventional PECVD processing tool, for example a for a radio-frequency-PECVD system. This system comprises a first electrode 10 and a second electrode 2 placed in a plasma reactor chamber, the first electrode 10 being spaced apart from the second electrode 2 by an inter-electrode volume. A RF-power supply 6 is electrically connected between the first electrode 10 and second electrode 2, so as to apply an RF voltage difference between the first and second electrodes. In this example, the second electrode 2 is electrically connected to ground, so that the first electrode 10 is the powered electrode. A substrate 5 is placed on the second electrode 2 so that a surface of the substrate 5 faces the first electrode 10. An input gas is introduced into the plasma reactor chamber at a chosen pressure P while applying the RF voltage between the first electrode 10 and the second electrode 2. The pressure P, distance D and applied voltage are adjusted so as to generate a plasma 20 between the first electrode assembly 1 and the surface 51 of the substrate 5. This first step enables for example deposition of a layer 30 having a uniform thickness (or non patterned) on the top surface of the substrate 5. For example, this first step may be used for depositing a p-doped or n-doped semiconducting layer, a dielectric layer and/or a passivation layer, such as intrinsic amorphous hydrogenated silicon (i) a-Si:H. As an option, by changing the input gas, this first step of FIG. 15 may also be used for cleaning or removing an oxide layer from the surface of the substrate 5 before deposition of the homogeneous layer 30.

We outline that the first step of homogeneous deposition may be achieved in the same reaction chamber as the second step, using for example the configuration described in relation with FIG. 4A or 5A.

Other known deposition techniques such as physical vapor deposition (PVD) may be used to achieve the first step and deposit a thin film uniformly on a substrate 5 in the another reaction chamber.

FIG. 16 illustrates an example of a processing tool and method to achieve the second step. The second step comprises applying an etching plasma to the thin film uniformly deposited during the first step, in order to produce a patterned thin film. The substrate 5 with the uniform layer 30 is placed in a radio-frequency capacitively coupled plasma system (RF-CCP) comprising a first electrode assembly 1 with protrusions 11 and recesses 12 and a second electrode assembly 2, as described above. In the second step, the plasma chemistry uses for example hydrogen (H₂) gas or a mixture of SF₆ and dioxygen (O₂) or a mixture of SiF₄ and argon. The protrusions 11 of the first electrode assembly 1 are placed at a distance less than a threshold distance from the second electrode assembly so that ignition of the plasma between the second electrode assembly and the protrusions 11 of the first electrode assembly 1 is inhibited. Localized plasma zones 26 ignite within the channels or holes 12 having characteristic dimensions larger than the threshold distance. The spatially selective ignition of the plasma 26 allows one to etch the previously deposited film 30 in predetermined areas without contacting the surface, thus achieving contactless masking. The second step forms openings 36 in the uniform layer 30, and thus generates patterned features 130 made of the material deposited uniformly during the first step. The dimensions and features sizes available for the patterned features 130 from this technique are of the order of a few hundreds of micrometers. Such dimensions and features sizes are compatible with those required for the fabrication of interdigitated back contacts (IBC) or point contact openings for solar cells.

Alternatively, the second step may be achieved using a first electrode configuration as disclosed in relation with FIG. 2, wherein plasma areas are generated between the protrusions 11 and the surface of the sample while plasma is prevented from being generated in the recesses 12.

It is possible, using the uniform deposition and selective etching process, to deposit isolated n-type and p-type fingers for IBC solar cells.

FIG. 17 shows an example process flow to deposit n-type and p-type fingers for IBC solar cells without using a mask in contact with the sample. FIG. 17A is similar to FIG. 15, and, respectively, FIG. 17B is similar to FIG. 16.

In the first step (FIG. 17A), a n-type material is deposited uniformly as a thin layer 30 on a substrate 5 by applying a plasma 20 in a gas mixture comprising n-type dopant gas. In the second step (FIG. 17B), the n-type layer 30 is etched in a patterned way by ignition of plasma zones 26 localized within the channels or holes 12. At the end of the second step, a n-type pattern 130 is obtained. In a third step (FIG. 17C), another plasma 200 is generated so as to deposited a p-type layer 38 uniformly on the substrate 5 and on the n-type pattern 130. In a fourth step (FIG. 17D), the p-type layer 38 is etched in a patterned way so as to remove selectively the p-type layer deposited on the n-type pattern 130 without etching the n-type pattern 130 and so as to isolate the p-type pattern 138 thus formed from the n-type pattern 130. The advantage of the deposition of an homogeneous layer 30, 38 followed by a patterned etching is that the quality of the deposited layers 30, 38 can be extremely high using known PECVD techniques. In addition, the profile of the patterned layer 130, 138 can be tuned according to specifications (for example aspect ratio, finger separation distance).

FIG. 18 shows an alternative example process flow to deposit n-type and p-type fingers for IBC solar cells without using a mask in contact with the sample. FIG. 18A is similar to FIG. 17A, and, respectively, FIG. 18B is similar to FIG. 17B. The third step (FIG. 18C) consists of a second patterned p-layer deposition step using the same electrode configuration as in the second step, preferably with modified process conditions so as to achieve a narrower deposition profile for the patterned p-layer 139 than for the patterned n-layer 130. More precisely, in the third step, a patterned p-layer 139 is deposited by ignition of another plasma 29 localized within the channels or holes 12 so as to deposited p-type material, without moving the first electrode assembly between the second step and the third step. At the end of the third step (FIG. 18C), a p-type pattern 139 is formed inside the openings 36 formed in the n-type layer during the second step. This process also enables to deposit isolated n-type and p-type fingers for IBC solar cells. This alternative process flow has the advantage of reducing the number of processing steps, thus reducing manufacturing costs. However, this alternative process raises challenges in achieving high quality patterned doped layer in the third step (FIG. 18C) and avoiding contamination from the etching of by products of the second step. Nevertheless, using this alternative process, if at least one of the layers can be deposited at high quality with a patterned deposition, the use of a patterned deposition step after the etching step using the same processing setup allows process steps reduction.

FIG. 8 represents schematically a cross-section of a plasma processing apparatus according to a second embodiment of the invention. The first electrode assembly 1 comprises a plurality of protrusions 11, and a plurality of cavities 15, each cavity 15 being connected to the inter-electrode volume by a channel 16. The protrusions 11 are placed at a distance D1 so as to prevent local plasma ignition between the surface 51 of the substrate 5 and the protrusions 11. The cavities are dimensioned so that their volume enables ignition of local plasma areas 25 inside each cavity 15. The channel 16 generally has a smaller lateral dimension than the cavity 15. The length and width of the channel are dimensioned so as to allow diffusion of the plasma 25 between the cavity 15 and the surface 51 of the sample 5. Thus, this second embodiment enables deposition of patterned layer 35 having approximately the transverse dimensions of the channels 16.

Of course, the second embodiment can also be used for local plasma etching, for example to produce openings in a dielectric layer.

The cavities 15 may have a one-dimensional or two-dimensional configuration.

For example, the cavities 15 and channels 16 have a one-dimension geometry extending longitudinally along the Y-axis, for generating patterns extending longitudinally on the surface of the sample along the Y-axis. In another example, the cavities 15 and channels 16 have a two-dimension geometry and for example, have a similar profile as illustrated on FIG. 8 along the Y axis, for generating patterns limited in both directions X and Y on the surface 51 of the sample 5. A first electrode assembly may comprise a combination of one-dimension and two-dimension cavities and channels, depending on the application.

The cavities 15 and channels 16 illustrated on FIG. 8 have a square or rectangular profile.

As compared to the first embodiment, the second embodiment enables forming patterns with smaller feature size, for example patterns having critical dimensions less than twice the sheath width of the plasma.

FIG. 9 represents a cross-section of different cavities 15 having a spherical (2D geometry) or cylindrical (1D geometry) shape and channels having a cylindrical (2D geometry) or slit shape (1D geometry).

A first electrode assembly as illustrated on FIG. 9 is used for depositing a-Si:H patterned layer, in a mixture of hydrogen and silane gas (H₂/SiH₄=100:2.5), under a pressure P of 1060 mTorr, with a power of 50 Watts. The widths of the patterned layers obtained are around 300 micrometers.

The cavities 15 can additionally be shaped to optimize the profile of the deposited film, or the uniformity of the flux to the area being processed.

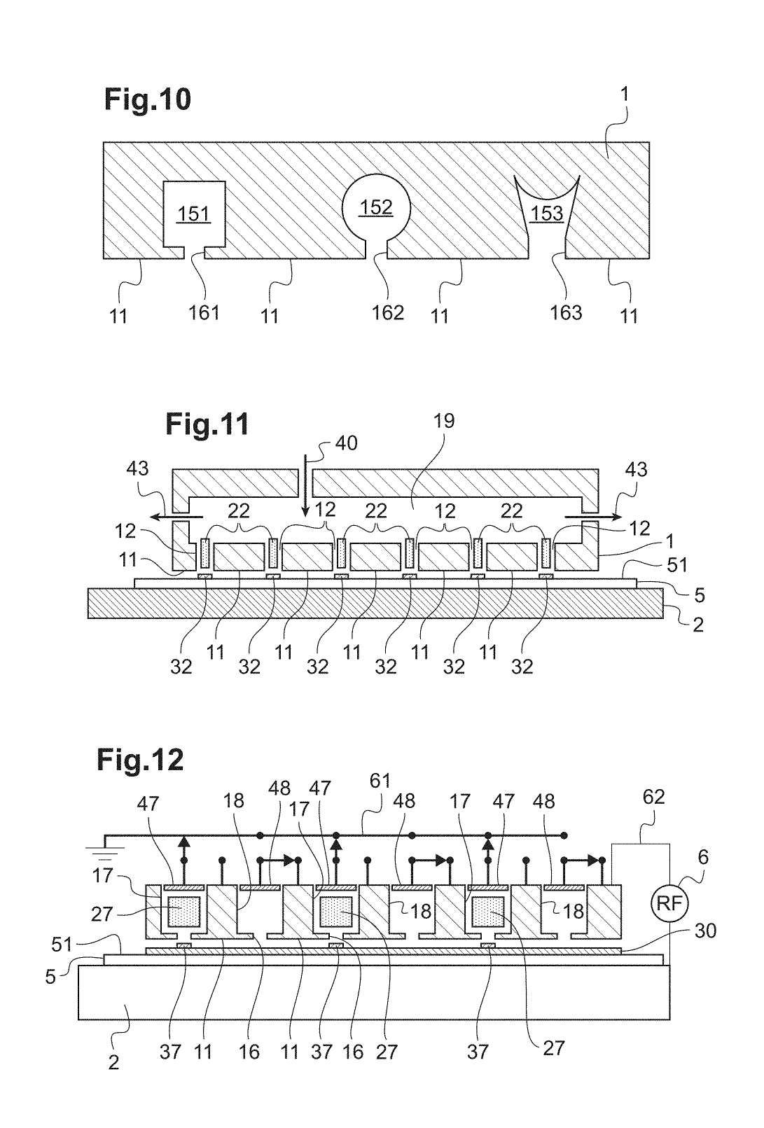

FIG. 10 illustrates different cavity profiles considered to control the shape of the critical dimensions or the edges of the pattern formed. The cavity 151 has a square or rectangular profile and is connected by a channel 161 to the inter-electrode volume. The cavity 152 has a spherical or cylindrical profile and is connected by a channel 162. The cavity 153 has a conical profile and is connected by a channel 163. The conical cavity 153 may have a flat, concave or convex bottom for controlling the critical dimensions of the pattern.

FIG. 11 represents a variant of the first electrode design wherein the hollows at the end of each channel 12 are fluidically connected to a common cavity 19. The cavity 19 is fluidically connected to a gas inlet 40 and to one or several gas outlets 43. This common cavity 19 enables a better distribution of input gas amongst channels 12. This configuration also enables connecting a secondary gas egress channel 43 to avoid the spreading of patterned features due to gas drag. The dimensions of the common cavity 19 and the channels 12 are chosen so that the plasma 22 ignites only nearby or within the channels 12. Optionally the channels 12 may be shaped to optimize the profile of the processed patterned areas 32 on the surface 51 of the sample.

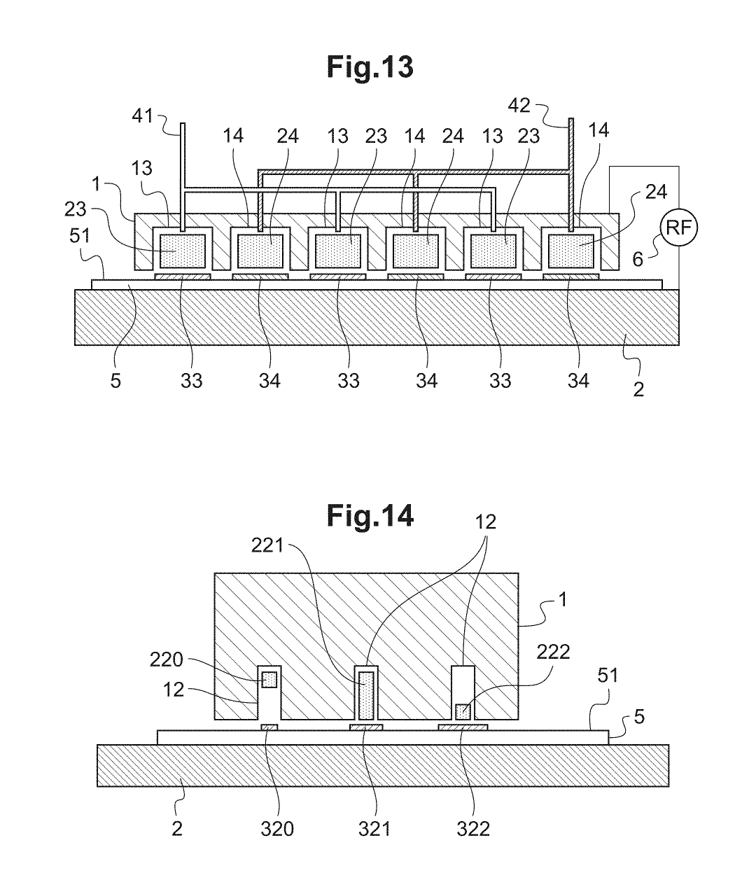

FIGS. 12 and 13 represent schematically variants of the electrode configuration, in cross-section.

In FIG. 12, the first electrode assembly comprises a first sub-set of cavities 17 and a second sub-set of cavities 18. Each cavity 17, 18 is fluidically connected by a channel 16 to the inter-electrode volume. Each cavity 17 of the first sub-set comprises a first sub-electrode 47. Respectively, each cavity 18 of the second sub-set of cavities comprises a second sub-electrode 48. For example, in a specific operating regime illustrated FIG. 11, the first sub-electrodes 47 are electrically connected to a ground line 61, while the second sub-electrodes 48 are electrically connected by a line 62 to the RF generator 6. The RF generator 6 is also electrically connected to the second electrode assembly 2. The first sub-electrodes 47 are electrically isolated from the second sub-electrodes 48. The second sub-electrodes 48 of the first electrode assembly 1 being at the same electric potential as the second electrode assembly 2, no plasma occurs in the second sub-set of cavities 18. In contrast, due to the electric potential difference between the first sub-electrodes 47 of the first electrode assembly 1 and the second electrode assembly 2, plasma 27 ignites in the first sub-set of cavities 17. Thus, the RF generator 6 selectively powers the first sub-set of cavities 17 without powering the second sub-set of cavities 18. As an example, this configuration enables depositing patterned layers 37 on top of an i-layer 30, the patterned layers 37 being formed selectively in front of the channels 16 connected to the first sub-set of cavities 17. This configuration requires the system to be operated in a regime where plasmas do not light within the cavities 18.

The electrical connections can advantageously be modified according to the needs, so that the RF generator 6 selectively powers the second sub-set of cavities 18 without powering the first sub-set of cavities 17. Alternatively, the plasma generating apparatus of FIG. 12 can be configured so that the RF generator 6 powers simultaneously the first sub-set of cavities 17 and the second sub-set of cavities 18. More generally, the plasma generating apparatus of FIG. 11 can be configured so that the RF generator 6 applies a first voltage difference to the first sub-electrodes 47 and a second voltage difference to the second sub-electrodes 48, so as to control the patterns formed.

The electric configuration of the first electrode assembly as illustrated on FIG. 11 can be modified in real time during a process flow.

FIG. 13 shows another first electrode assembly configuration comprising a first sub-set of cavities 13 and a second sub-set of cavities 14. The gas feed assembly comprises two independent input gas lines. A first input gas line 41 injects a first input gas in the first sub-set of cavities 13. Respectively, a second input gas line 42 injects a second input gas in the second sub-set of cavities 14. The RF generator 6 is connected to first electrode assembly 1 and powers simultaneously powered by the first and second sub-set of cavities 13, 14.

The configuration of FIG. 13 enables the RF generator 6 to ignite both plasma areas 23 based on the first input gas in the first sub-set of cavities 13, and simultaneously the second plasma areas 24 based on the second input gas in the second sub-set of cavities 14. This configuration enables simultaneous deposition of a first pattern 33 in front of the first sub-set of cavities 13 and a second pattern 34 in front of the second sub-set of cavities 14. For example, different doping gases 41, 42 are injected into alternating plasma zones 23, 24, enabling the simultaneous deposition of p-doped 33 and n-doped 34 patterned layers. Advantageously, the gas injection is performed through the first electrode assembly and into the volumes where plasma ignition has occurred, and the gas exit out of each subset of cavities is through an additional hole at the edge of the electrode, minimizing the gas flow through the channels. Alternatively, a quenching gas may be injected into cavities 14 to prevent ignition in these cavities 14, while allowing ignition and deposition in the other cavities 13.

The variants of the first electrode configuration described in relation with FIGS. 12 and 13 enable a similar process flow as described in relation with FIGS. 5A-5C, but without requiring any mechanical movement within the plasma reactor chamber.

Those skilled in the art will recognize that configurations combining selective electric control and selective gas injection into/for sub-sets of cavities or recesses are also contemplated without departing from the frame of the present disclosure.

A further variant on the use of the plasma generating apparatus involves the selection of the voltage difference waveform to be applied. The use of a sinusoidally varying voltage composed of a single frequency between 500 kHz and 100 MHz may be used. Alternatively, the simultaneous use of multiple frequencies is considered. In a particularly advantageous variant, the application of multiple harmonics of a base frequency (in the range from 500 kHz to 100 MHz) is considered. Depending on the respective phase between the harmonics and their respective amplitude, such waveforms can appear as a series of peaks, valleys, or as sawtooth waveforms. For example, FIG. 14 shows a first electrode assembly 1 comprising a plurality of recesses 12. The recesses 12 have the same shape, dimensions and are placed at the same distance from the surface 51 of the substrate 5. FIG. 14 represents schematically the position of the plasma areas 220, 221, 222 corresponding to different voltage waveforms, the other plasma parameters being identical (input gas, pressure). The use of sawtooth waveforms is of considerable interest for the electrode designs described in the present disclosure, as such waveforms allow one to control the spatial distribution of the most intense region of the plasma, as shown in FIG. 14. More precisely, we observe that the first plasma area 220 generated using a first sawtooth waveform voltage is located in the bottom of the recess 12 far from the sample surface, whereas the plasma area 221 generated using a second sawtooth waveform voltage is centered inside the recess 12, and the third plasma area 222 generated using a third sawtooth waveform voltage is located at the opening of the recess 12 close to the sample surface. As precursors leave the plasma, the shadowing effect of the channel walls have a varying impact on the spreading of the processed areas depending on the proximity of the plasma zone 220, respectively 221, 222 to the substrate surface. The use of such sawtooth waveforms combined with all the variants of electrode geometries, therefore, can be used to further control the profile of the deposition/etching at the surface.

The main application of the plasma generating apparatus and process disclosed herein is the formation of interdigitated back contacts or dielectric openings for the manufacture of high-efficiency crystalline silicon solar cells.

The invention allows the implementation of high-performance elements, already used in industry, with a far simpler and cheaper process. No loss in performance should be expected using the plasma lithography process and apparatus. The invention can easily be implemented on existing tools only at the expense of changing one of the electrodes of a plasma processing apparatus.

The present disclosure enables the formation of the IBC contacts in a single process step, at low temperature, and with the possibility to use a thin intrinsic a-Si:H passivation layer in the same plasma reaction chamber. The method and apparatus enable the use of both the IBC configuration combined with a HIT passivation step, without adding any additional processing step in the cell fabrication process flow. The method offers the advantage of being contactless which solves an important problems, as the surface of the clean wafer (with oxide removed) is very sensitive to damage and contamination.

Any plasma processing step that requires the activation of species by plasma can be utilized with this method. The technique, therefore, is equally useful for processes such as but not limited to deposition, etching, cleaning, densification and functionalization.

The invention finds a most suitable application in the deposition of interdigitated contacts in interdigitated back contact (IBC) and for dielectric openings in solar cells for point contacts.

The plasma lithography as disclosed herein also applies to the manufacture of other photovoltaic devices, photodetectors and sensors.

1-18. (canceled)

19. Plasma generating apparatus for manufacturing patterned devices comprising:
a) a plasma reactor chamber;
b) a gas feed assembly for introducing an input gas into the plasma reactor chamber at a chosen pressure (P);
c) a first electrode assembly (1) and a second electrode assembly (2) placed in the plasma reactor chamber, the first electrode assembly (1) being spaced apart from the second electrode assembly (2) by an inter-electrode volume, and
d) an electrical power supply (6) for generating a voltage difference between the first electrode assembly (1) and the second electrode assembly (2);
wherein:
e) the first electrode assembly (1) comprises a plurality of protrusions (11) and a plurality of recesses (12, 13, 14, 15, 16, 17, 18),
f) the second electrode assembly (2) is configured for receiving a substrate (5) having a surface (51) facing the plurality of protrusions (11) and the plurality of recesses (12, 13, 14, 15, 16, 17, 18);
g) the protrusions (11) and the recesses (12, 13, 14, 15, 16, 17, 18) being dimensioned and set at respective distances (D1, D2) from the surface (51) of the substrate (5) so as to generate a plurality of spatially isolated plasma zones (21, 22) located selectively either between said surface of the substrate (5) and said plurality of recesses (12, 13, 14, 15, 16, 17, 18) or between said surface of the substrate (5) and said plurality of protrusions (11) at the chosen pressure (P) of the input gas.

20. Plasma generating apparatus according to claim 19 wherein the recesses (12) are dimensioned and placed at a second distance (D2) from the surface (51) of the substrate (5) such that for the applied voltage difference V(t), a product of the chosen pressure and the second distance is comprised between a first plasma ignition threshold (T1) and a second plasma extinction threshold (T2) and wherein the protrusions (11) are dimensioned and placed at a first distance (D1) from the surface (51) of the substrate (5) such that for the applied voltage difference V(t), another product of the chosen pressure (P) and the first distance (D1) is lower than the first plasma ignition threshold (T1), so that the plasma generating apparatus generates spatially isolated plasma zones (22) between the surface of the substrate (5) and the recesses (12) without generating plasma locally between the surface of the substrate (5) and the protrusions (11).

21. Plasma generating apparatus according to claim 19 wherein the protrusions (11) are dimensioned and placed at a first distance (D1) from the surface (51) of the substrate (5) such that for the applied voltage difference V(t), a product of the pressure (P) and the first distance (D1) is comprised between a first plasma ignition threshold (T1) and a second plasma extinction threshold (T2) and wherein the recesses (12) are dimensioned and placed at a second distance (D2) from the surface (51) of the substrate (5) such that for the applied voltage difference V(t), a product of the chosen pressure (P) and the second distance (D2) is larger than the second plasma extinction threshold (T2), so that the plasma generating apparatus generates spatially isolated plasma zones (21) between the surface of the substrate (5) and the protrusions (11) without generating plasma locally between the surface of the substrate (5) and the recesses (12).

22. Plasma generating apparatus according to claim 19 wherein the first electrode assembly (1) comprises at least a first and a second part (111, 121), the first part (111) being mobile relatively to the second part (121) between a first position and a second position, such that, in the first position said first electrode assembly (1) forms a plurality of protrusions (11) and a plurality of recesses (12), and, in the second position, the first electrode assembly (1) forms a flat surface facing the surface of the substrate (5).

23. Plasma generating apparatus according to claim 19 wherein the plurality of recesses (12, 13, 14, 15, 16, 17, 18) comprises a plurality of cavities (15, 151, 152, 153) each cavity (15, 151, 152, 153) being connected to the inter-electrode volume by a channel (16, 161, 162, 163), the cavities (15, 151, 152, 153) being dimensioned such that the apparatus generates plasma (25) within said cavities (15, 151, 152, 153) at the chosen pressure (P), and the channels (16, 161, 162, 163) being dimensioned such that the plasma (25) generated in the cavities (15, 151, 152, 153) diffuses toward the inter-electrode volume.

24. Plasma generating apparatus according to claim 19 wherein the plurality of recesses (12, 13, 14, 15, 16, 17, 18) comprises a plurality of channels (12) connected to a common cavity (19), the common cavity (19) being connected to at least one gas inlet (40) and to at least one gas outlet (43).

25. Plasma generating apparatus according to claim 23 wherein said cavity (15, 19, 151, 152, 153) has a square, rectangular, spherical or conic profile and/or wherein the channels (12, 16) have a cross-section shape chosen among a rectangular, trapezoidal, conical or cylindrical shape, or a shape chosen to generate a pattern with determined spatial profile on the surface (51) of the substrate (5).

26. Plasma generating apparatus according to claim 24 wherein said cavity (15, 19, 151, 152, 153) has a square, rectangular, spherical or conic profile and/or wherein the channels (12, 16) have a cross-section shape chosen among a rectangular, trapezoidal, conical or cylindrical shape, or a shape chosen to generate a pattern with determined spatial profile on the surface (51) of the substrate (5).

27. Plasma generating apparatus according to claim 19 wherein the first electrode assembly (1) comprises at least a first and a second sub-set of recesses (17, 18), the first sub-set of recesses (17) being electrically isolated from the second sub-set of recesses (18), and the first electrode assembly (1) comprising a first and a second sub-electrodes (47, 48), the first, respectively second, sub-electrode (47, 48) electrically connecting the first, respectively second, sub-set of recesses (17, 18), and wherein the electrical power supply (6) is configured for generating a first, respectively a second, voltage difference between the first, respectively second, sub-electrodes (47, 78) and the second electrode assembly (2).

28. Plasma generating apparatus according to claim 19 wherein the first electrode assembly (1) comprises at least a first and a second sub-sets of recesses (13, 14), and wherein the gas feed assembly comprises a first and a second input gas line (41, 42), the first, respectively second, gas line (41, 42) being in fluidic communication with the first, respectively second, sub-set of recesses (13, 14), so as to inject a first, respectively second, input gas into the first, respectively second, sub-set of recesses (13, 14).

29. Plasma generating apparatus according to claim 27 wherein the first electrode assembly (1) comprises at least a first and a second sub-sets of recesses (13, 14), and wherein the gas feed assembly comprises a first and a second input gas line (41, 42), the first, respectively second, gas line (41, 42) being in fluidic communication with the first, respectively second, sub-set of recesses (13, 14), so as to inject a first, respectively second, input gas into the first, respectively second, sub-set of recesses (13, 14).

30. Plasma generating apparatus according to claim 19 wherein said plurality of protrusions (11) and said plurality of recesses (12, 13, 14, 15, 16, 17, 18) are arranged in a one-dimension or two-dimensional periodic array.

31. Plasma generating apparatus according to claim 19 wherein said first electrode assembly (1) and/or said second electrode assembly (2) is mounted on a translation or rotating stage.

32. Plasma generating apparatus according to claim 19 wherein the electrical power supply (6) is configured for generating a voltage difference to be applied between the first and second electrodes, wherein the voltage difference is constant over time, or wherein the voltage difference is time-varying and comprises a single base frequency in the range between 500 kHz and 100 MHz or comprises a plurality of harmonics of a base frequency in the range between 500 kHz and 100 MHz, and wherein the respective amplitudes and phases of the plurality of harmonics are selected so as to generate voltage difference having waveform with an amplitude asymmetry and/or with a slope asymmetry.

33. Method of manufacturing patterned devices using spatially resolved plasma processing comprising the steps of:
a) Placing a substrate (5) in a plasma reactor chamber of a plasma generating apparatus, the substrate (5) being in contact with a second electrode assembly (2) and having a surface (51) facing a first electrode assembly (1) comprising a plurality of protrusions (11) and a plurality of recesses (12, 13, 14, 15, 16, 17, 18);
b) Injecting an input gas or gas mixture into the plasma reactor chamber under a chosen pressure (P);
c) configuring the first electrode assembly (1) such the protrusions (11) are at a first distance (D1) and the recesses (12) are at a second distance (D2) from the surface (51) of the substrate (5),
d) Applying a voltage difference between the first electrode assembly (1) and the second electrode assembly (2), the protrusions (11) and recesses (12, 13, 14, 15, 16, 17, 18) being dimensioned and set at respective distances (D1, D2) from the surface (51) of the substrate (5) so as to generate a plurality of spatially isolated plasma zones (21, 22) located selectively either between the surface (51) of the substrate (5) and the plurality of recesses (12) or between the surface (51) of the substrate (5) and the plurality of protrusions (11), so as to form a pattern on the surface of the substrate (5).

34. Method of manufacturing patterned devices according to claim 33 further comprising a step of:
e) electrically isolating a first sub-set of recesses (17) from a second sub-set of recesses (18) of the first electrode assembly (1); and
f) Applying a first, respectively, second, voltage difference between the second electrode assembly (2) and the first respectively, second, sub-set of recesses (17, 18).

35. Method of manufacturing patterned devices according to claim 33 further comprising the steps of:
g) Fluidic connection of a first, respectively second, gas line (41, 42) to a first, respectively second, sub-set of recesses (13, 14) of the first electrode assembly (1); and
h) Injecting a first, respectively second, input gas into the first, respectively second, sub-set of recesses (13, 14).

36. Method of manufacturing patterned devices according to claim 33 further comprising, prior to step a):
an initial step of depositing an homogeneous layer (30) on the surface (51) of the substrate intended to be facing the first electrode assembly (1) at step a), and wherein the input gas or gas mixture injected at step b) is selected so that the spatially isolated plasma zones (26) generated at step d) produce spatially selective etching of the homogeneous layer (30) so as to form a patterned layer (130) by etching openings (36) in the homogeneous layer (30).

37. Method of manufacturing patterned devices according to claim 36 further comprising, after step d):
i) Another step of depositing another homogeneous layer (38) on the openings (36) and on the patterned layer (130);
j) applying another series of steps a, b), c) and d) wherein the input gas or gas mixture injected at said another step b) is selected so that the spatially isolated plasma zones (28) generated at said another step d) produce spatially selective etching of said another homogeneous layer (38) on the patterned layer (130) and so as to form another patterned layer (138) in the openings (36) of the patterned layer (130).

38. Method of manufacturing patterned devices according to claim 36 further comprising, after step d):
k) applying another series of steps a, b), c) and d) wherein the input gas or gas mixture injected at said another step b) is selected so that the spatially isolated plasma zones (29) generated at said another step d) produce spatially selective deposition of another patterned layer (139) in the openings (36) of the patterned layer (130).
